(19) United States
(12) Patent Application Publication
(10) Pub. No.: US 2008/0309332 A1
(43) Pub. Date: Dec. 18, 2008

(54) Microchip Assembly With Short-Distance Interaction

(75) Inventor: Josephus Arnoldus Henricus Maria Kahlman, Tilburg (NL)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 11/996,296

(22) PCT Filed: Jul. 12, 2006
(86) PCT No.: PCT/IB2006/052360

§ 371 Date: Jan. 21, 2008

(30) Foreign Application Priority Data
Jul. 21, 2005 (EP) 05106682.7

(51) Int. Cl. G01R 33/00; H01L 21/00; H01L 29/82

(52) U.S. Cl. 324/260; 438/64; 257/428; 257/E21.04

(57) ABSTRACT

The invention relates to a microchip assembly that is particularly applicable for biosensors. According to the invention, short-distance interactions between coupling circuits (11, 12) on a thin substrate (13) and an object (2) take place through the substrate (13) of reduced thickness (d). The coupling circuits may particularly comprise wires (11) for the generation of a magnetic field (B) and a GMR (12) for the detection of the stray fields (B′) generated by magnetizing beads (2) on labeled biological molecules (1).

The invention relates to a microchip assembly comprising a microelectronic chip with coupling circuits that are adapted for a short-distance wireless physical interaction, for example the generation and/or detection of electromagnetic fields. The invention further relates to a microfluidic device comprising such a microchip assembly and a process for the production of a chip for such a microchip assembly.

From the WO 2005/010543 A1 and WO 2005/010542 A2 a microchip assembly is known which may for example be used in a microfluidic biosensor for the detection of biological molecules. The microchip assembly comprises (i) sample locations in the form of microfluidic channels in which molecules labeled with magnetic beads can be provided, and (ii) sensor chips with coupling circuits comprising wires for the generation of a magnetic field and Giant Magneto Resistances (GMR) for the detection of stray fields generated by magnetized beads. The coupling circuits are fabricated at a “sensitive side” of the chip on a semiconductor substrate, and each sensor chip is attached behind a hole in the wall of a microfluidic channel with its sensitive side facing the channel. A disadvantage of these known devices is that the sample fluid has to dive into a recess to reach the sensitive chip surface. This may create regions of low or stagnant flow and generally impairs the measurement.

Based on this situation it was an object of the present invention to provide means that particularly allow the construction of an improved microfluidic device of the kind described above.

This object is achieved by a microchip assembly according to claim 1, by a microfluidic device according to claim 8, and by a process according to claim 14. Preferred embodiments are disclosed in the dependent claims.

According to its first aspect, the invention relates to a microchip assembly comprising the following components:
a) a microelectronic chip with coupling circuits on a substrate, the coupling circuits being adapted to perform and process a wireless physical interaction over a short distance;
b) a sample location for providing an object that can (wirelessly and physically) interact with the coupling circuits;
wherein the substrate is disposed between the coupling circuits and the sample location.

The substrate on which the coupling circuits are disposed or fabricated may particularly be one of the known semiconductor materials like silicon Si, GaAs, SiO₂, polymers or mixtures thereof. Typically, there is an intimate contact and junction between substrate and coupling circuits, with the circuits for example being generated by doping in the surface layers of the substrate and/or by deposition of material on said surface.

The physical interaction that the coupling circuits are able to perform may particularly comprise the generation and/or detection of electromagnetic fields, wherein this term shall comprise pure magnetic fields and pure electric fields. It may however also involve other physical phenomena (e.g. thermal conduction) that are capable to act over short distances. The term “short-distance” shall denote in this context a distance in the order of the extensions of the microchip, particularly in the order the thickness of the chip or its components. Therefore, a “short distance” may typically range from zero up to 100 μm, preferably up to 10 μm, most preferably up to 1 μm. It should be noted that the coupling circuits are also capable to process the physical interactions. This shall quite generally mean that they have a controllable influence on these interactions and/or that they are influenced by the interactions in a controllable way. This distinguishes the coupling circuits from usual circuits of a microchip, which are of course also subject to physical interactions, but wherein said interactions are only (undesired) interferences and effectively without influence on the normal processing function of the circuits. In contrast to this, the coupling circuits are particularly designed to exploit the experienced wireless physical interactions.

In the known microchip assemblies for biosensors, the coupling circuits are disposed as close as possible to the sensitive side of the sensor chip and thus to the sample location containing for example labeled molecules. In the microchip assembly described here, however, the substrate is disposed between the sensitive coupling circuits and the sample location. It turns out that this arrangement implies a number of advantages which will become more clear in connection with the description of preferred embodiments of the invention. One of the advantages relies on the fact that the coupling circuits are protected by the substrate from a direct contact to the samples.

As the short-distance wireless physical interaction between the coupling circuits and an object at the sample location must take place through the substrate, the thickness of said substrate (measured in a direction pointing from the coupling circuits to the sample location, i.e. along the propagation direction of the physical interaction) is preferably less than 100 μm, most preferably less than 10 μm. The lower limit of the substrate-thickness is in principal only limited by the technical possibilities and may typically be in the order of 1 μm.

According to a particular embodiment of the invention, the coupling circuits comprise circuits for the generation of an electromagnetic field, for example wires through which (AC or DC) currents can be directed to generate (alternating or static) magnetic fields. Additionally or alternatively, the coupling circuits may comprise circuits for the detection of an electromagnetic field, particularly a magnetic sensor device like a Giant Magneto Resistance (GMR) for the detection of magnetic fields. If both circuits for the generation and the detection of electromagnetic fields are provided, the microchip assembly is especially apt for biosensor applications of the kind referred to above.

As was already mentioned, the microchip assembly may preferably be applied in microfluidic devices. In this case, the sample location will be a chamber of the microfluidic device that can be filled with a (gaseous, liquid or solid) sample. The chamber may particularly be a fluid channel of the microfluidic device or a chamber (well) of a microtiter plate. Moreover, the sample location may optionally be filled with a porous medium (e.g. nitro cellulose).

According to another modification of the microchip assembly, the side of the substrate that faces the sample location is covered with a coating. This coating may particularly comprise a material like gold which improves the surface chemistry with respect to an intended application. Such an advantageous coating can usually not be applied in known microchip assemblies as it would have to contact the coupling circuits (a metal would then for example generate short circuits).

According to another optional improvement of the microchip assembly, the coupling circuits are covered on their side that is opposite to the substrate with a carrier layer. The carrier layer may consist of the same material as the substrate, for example of a semiconductor material. Moreover, the carrier layer may preferably comprise electrically conductive feedthrough passages (called VIAs in the following) for contacting the coupling circuits. A carrier layer provides stability and stiffness to the chip if these cannot be sufficiently provided by a substrate of reduced thickness.

In a further development of the microchip assembly, the side of the chip that is opposite to the substrate (i.e. the “front side” or “sensitive side”) is bonded to a second microchip, particularly to a signal processing chip. The term “bonding” is used here as usual for a mechanical and simultaneously electrical coupling between the electrical contact pads of the chips. In many cases, the coupling circuits and the associated signal processing circuits have to be realized on separate chips because they are based on different technologies (for example on the use of copper as GMR material on the one hand and of CMOS technology on the other hand). The proposed direct or “flip-chip” bonding between the microchips is then very advantageous because the signal bandwidth will not be limited by long electrical leads. It should be noted that this positive effect is based on the fact that the chip faces the sample location with its substrate while the coupling circuits are turned away from the sample.

The microchip assembly may optionally comprise means for a wireless communication with external devices, for example antennas and/or photodiodes for an autonomous energy supply. In this case no galvanic coupling to external devices is necessary.

The invention further relates to a microfluidic device, particularly a microfluidic biosensor or a microtiter plate, which comprises a microchip assembly of the kind described above, wherein the sample location of the microchip assembly is constituted by a sample chamber of the microfluidic device. Said sample chamber may for example be a fluid channel of a biosensor or a well of a microtiter plate. The associated coupling circuits may particularly be designed to detect certain molecules in a sample that is provided in the microfluidic device, for example to detect or measure the concentration of molecules labeled with magnetized beads.

There are several possibilities to dispose the microchip with respect to the sample chamber in a microfluidic device of the kind described above. According to a first embodiment, the chip is attached to the inner side of a wall of the sample clamber, i.e. it is located completely inside the chamber. As the thickness of the chip is a relatively small due to the reduced size of the substrate, it can be disposed in the sample chamber without substantially disturbing the microfluidic functions thereof.

In the aforementioned embodiment, a mechanical support is preferably disposed between the chip and the respective wall of the sample chamber. Such a support stabilizes the arrangement and protects the chip from breakage, though it may not be necessary for the attachment of the chip to the wall (which is typically achieved by bonding).

According to a second embodiment of the microfluidic device, the microchip is integrated into a wall of the sample chamber. In this case, the microchip does not protrude into the sample chamber, thus leaving the microfluidic properties of the sample chamber completely unchanged.

In a preferred embodiment of the invention, at least one wall of the sample chamber of the microfluidic device is a molded interconnection device (MID) or a flex foil. In this case, the chip can be directly bonded to said wall for electrical connection. If necessary, the flex foil may be provided with an extra stiffness.

As the (front) side of the microchip opposite to the substrate normally contains sensible electronic circuitry (e.g. the coupling circuits), it is preferably sealed against the sample chamber to prevent contamination by sample material. Such a sealing may for example be achieved by glue or edges or rings of photoresist.

The invention further relates to a process for the production of the chip of a microchip assembly of the kind described above, i.e. a chip with coupling circuits on a substrate wherein a short-distance wireless interaction between the coupling circuits and an object may take place through the substrate. The process comprises the following steps:
a) generation of the coupling circuits on a substrate block, wherein said substrate block has a first thickness compared to the final substrate of the microchip;
b) reducing the aforementioned first thickness of the substrate block to the thickness of the final substrate, wherein said reduction is preferably achieved by etching.

The first thickness of the substrate block is typically chosen large enough to provide sufficient mechanical stiffness to the chip during its production. The ratio between first thickness and final thickness typically ranges from 100:1 to 2:1, most preferably being 10:1.

According to a further development of the process, the coupling circuits are attached to a permanent carrier layer and/or a temporary carrier layer before the thickness of the substrate block is reduced in step b). The carrier layer then substitutes the mechanical stability that will be lost by the thickness reduction of the substrate.

These and other aspects of the invention will be apparent from and elucidated with reference to the embodiment(s) described hereinafter. Like reference numbers in the Figures refer to identical or similar components.

In the following the invention is described by way of example with the help of the accompanying schematic drawings in which:

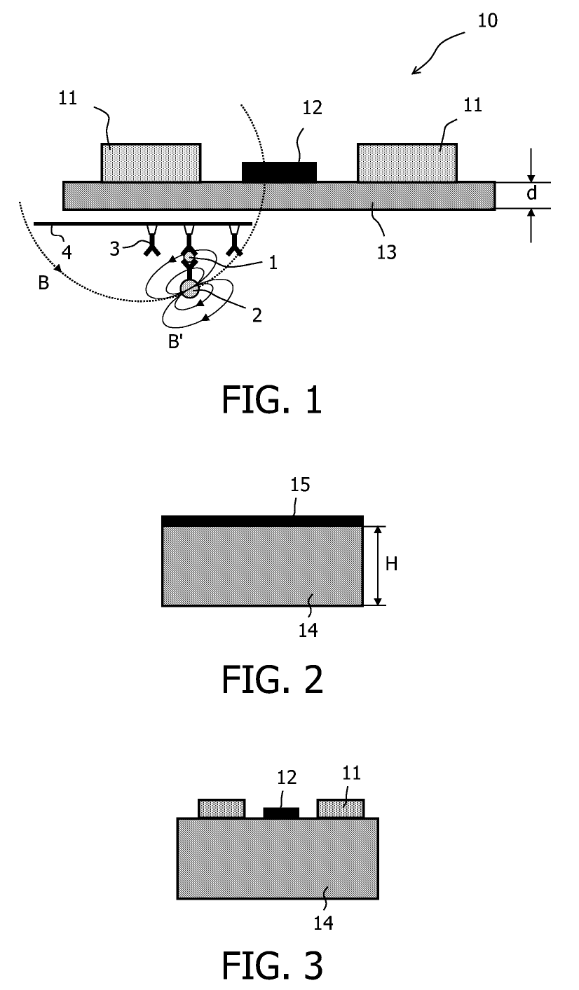

FIG. 1 shows an example of a sensor chip for a microchip assembly according to the present invention;

FIGS. 2-7 illustrate consecutive steps of the production of a microchip assembly according to the present invention;

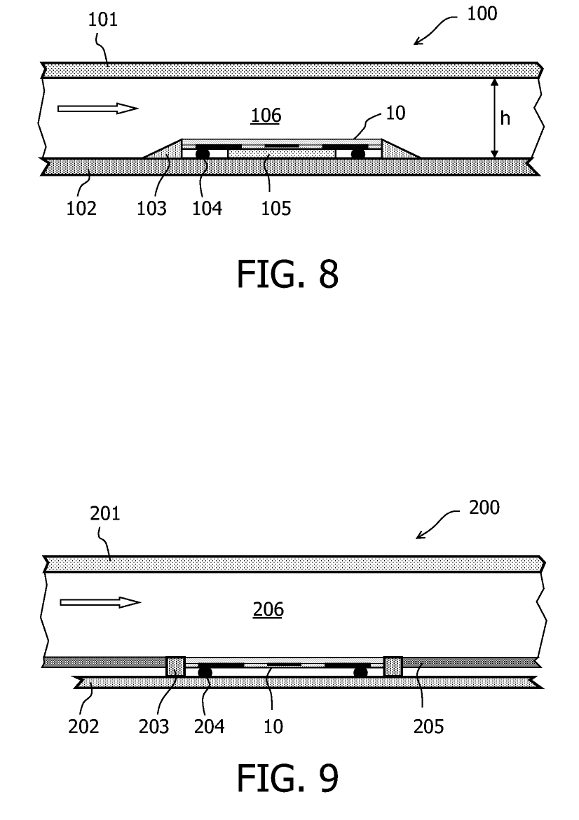

FIG. 8 shows a section through a microfluidic biosensor with a sensor chip inside the fluid channel;

FIG. 9 shows a section through a microfluidic biosensor with a sensor chip integrated into one of the channel walls;

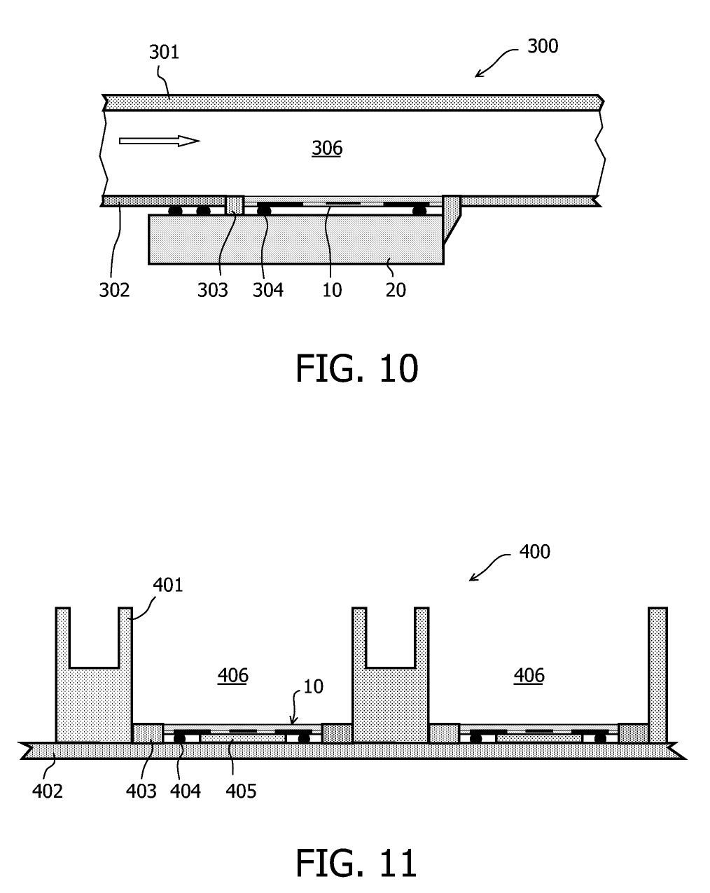

FIG. 10 shows a variant of the design of FIG. 9, wherein a signal processing chip is bonded to the sensor chip;

FIG. 11 shows a section through a microtiter plate with microchip assemblies according to the present invention located at the bottom of the wells.

The following description of the invention is based on the example of a magnetic biosensor or biochip, though the invention is not limited thereto and can be applied to all sensors that can measure through a layer with a thickness of a few micrometers.

Magneto-resistive biochips have promising properties for bio-molecular diagnostics, in terms of sensitivity, specificity, integration, ease of use, and costs. Examples of such biochips are for example described in WO 2003/054566, WO 2003/054523, WO 2005/010542 A2, WO 2005/010543 A1 or Rife et al. (Sens. Act. A vol. 107, p. 209 (2003)), which are incorporated into the present application by reference. The known biosensors have however several drawbacks, namely:
Only a small amount of the main liquid flow will reach the sensor surface as it is located in a cavity of the sample chamber wall.
A large liquid flow is required to remove air bubbles from the cavity.
(These first two problems increase the amount of required antigens and magnetic beads, they complicate washing and fluid handling in the cartridge and they are not compatible with an in-expensive, easy to use and disposable biosensor.)
The relatively long connection wires from the sensor to the pre-processing circuitry limit the electrical bandwidth of the detection system and may introduce noise. Due to the process incompatibility between the GMR sensor material (Cu) and CMOS it is not possible to integrate both functions. As a result two chips (system-on-chip: GMR+CMOS) must be connected. In the current geometry it is not possible to connect said chips close enough to the sensor in order to implement a large bandwidth, e.g. of more than 1 GHz, which is required to distinguish between magnetic beads properties (barcoding).

The origin of these drawbacks is quite principally: the sensitive surface of the sensor and the sensor connections are located in the same plane. A solution for this problem is to contact the sensor at its sensitive plane and to perform measurements at a plane, which is not its sensitive plane. This idea may be realized by thinning the sensor chip, flipping the chip upside down and measuring through the substrate side of the chip. This approach will generate an exclusion zone without beads between the sensor and the chip surface. Therefore this method is very suitable for measuring beads in a volume (bulk measurement).

FIG. 1 schematically shows a microchip or sensor chip 10, which implements the aforementioned ideas. As in sensor chips known from the state-of-the-art, the chip 10 comprises a substrate layer (or short “substrate”) 13 which may be a typical semiconductor like silicon. On the upper side of the substrate 13 (called “front side” in the following) are coupling circuits comprising two metal wires 11 and a Giant Magneto Resistance (GMR) 12. A biosensor consisting of an array of (e.g. 100) such sensor chips 10 for the detection of superparamagnetic beads may be used to simultaneously measure the concentration of a large number of different biological molecules 1 (e.g. protein, amino acids, DNA) in a solution (e.g. blood or saliva). In one possible example of a binding scheme, the so-called “sandwich assay”, this is achieved by providing a binding surface 4 with first antibodies 3, to which the target molecules 1 may bind. Superparamagnetic beads 2 carrying second antibodies may then attach to the bound target molecules 1. A current flowing in the wires 11 then generates a magnetic field B, which then magnetizes the super paramagnetic beads 2. The stray field B′ from the superparamagnetic beads 2 introduces an in-plane magnetization component in the GMR 12, which results in a measurable resistance change.

In contrast to known biosensor applications, the magnetic beads 2 to be detected are disposed on the other side of the substrate layer 13 in a microchip assembly according to the present invention. The interaction therefore has to take place through the substrate 13, which is made possible by a largely reduced thickness d of the substrate. In typical examples, the reduced thickness d ranges from 20 μm to 1 μm.

FIG. 2 shows a first step in a preferred production process of a microchip assembly according to the present invention (note that processing steps known to a person skilled in the art will not explained in detail here). The production starts with a semiconductor wafer or substrate block 14 with a layer 15 of the GMR material on top (wherein the terms top, left etc. refer to the orientations in FIGS. 2-7). The substrate block 14 has a first, “additional” thickness H of typically 100 μm to 1000 μm, which corresponds to the usual thickness of substrates in known sensor chips.

In FIG. 3, the GMR material has the reduced to the layout of wires 12 as needed, and the material of the wires 11 has been deposited on the substrate block 14. The wires 11, 12 then constitute “coupling circuits” for the detection/generation of magnetic fields.

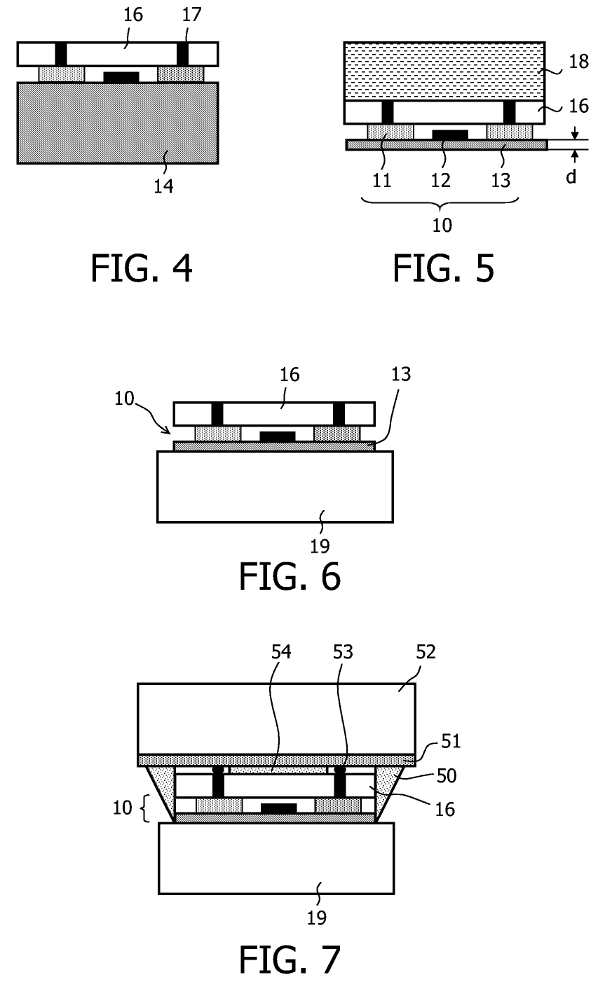

FIG. 4 shows an optional step, wherein an additional permanent carrier layer 16 is grown on the coupling circuits 11, 12, said layer 16 comprising electrical feedthroughs or VIAs 17 for an electrical connection to the wires 11 and GMR 12.

In the stage shown in FIG. 5, a temporary carrier layer in the form of glass 18 has been attached on top of the arrangement (i.e. on the permanent carrier layer 16). Moreover, the substrate block 14 has been etched to the largely reduced final thickness d, resulting in the thin final substrate 13.

In FIG. 6, the temporary carrier 18 has been removed from the top of the arrangement, and a temporary extra mechanical stiffness 19 has instead been attached to its bottom side, i.e. to the substrate 13. The wafer has then been sawed to produce single microchips.

FIG. 7 shows the further processing of the microchip 10 and its (optional) carrier layer 16 and temporary mechanical stiffness 19. A flex foil 51 is attached on top of the carrier layer 16 and contacted to the VIAs (and thus to the wires 11 and GMR 12) by bumps 53. An additional layer 54 between the flex foil 51 and the carrier layer 16 provides additional mechanical stability. Moreover, the whole flex foil 51 may be stabilized by another extra mechanical stiffness 52 attached to its top. Finally, the lateral sides of the microchip arrangement are sealed and stabilized by a surrounding ring of glue 50. After removal of the extra mechanical stiffness 19, the substrate surface may be functionalized to apply the biological assay.

FIG. 8 shows a section through the channel 106 of a first microfluidic biosensor 100 that comprises a microchip 10 of the kind described above (without the optional carrier layer 16). A sample fluid may flow in the direction of the arrow through the channel of height h (typically 70-100 μm) which is bounded by a cartridge cover 101 and a bottom wall 102. Said bottom wall may particularly be realized by flex foil 102 or a molded interconnection device (MID).

The microchip 10 is completely arranged inside the fluid channel 106 with its substrate side oriented towards said channel and with its sensitive side oriented downwards. The sensitive side of the microchip 10 is connected by flip-chip like bumps 104 to the flex foil or MID 102. Though the sensitive layer of the chip 10 points towards the flex foil 102, there exists enough sensitivity to detect beads in the flow channel 106 due the thinness of the sensor chip (or, more precisely, its substrate).

If desired the sensor chip 10 may be mechanically supported by layer 105, and the flex may be made extra stiff. Furthermore, the substrate side of the chip, which points to the liquid, may be covered up with gold (Au) or another material to ease the surface chemistry.

Glue 103 is applied at the lateral sides of the chip 10 to seal the electrical wiring and to avoid direct contact between wiring and fluids. Special measures can be applied to the chip to avoid capillary flow of glue over the chip, e.g. an edge or a ring of SU8 can be applied (all discussed measures can be applied to all embodiments described here).

FIG. 9 schematically shows a second embodiment of a microfluidic biosensor 200 with a microchip 10 of the kind described above. Note that in FIGS. 8 to 11 the reference numbers of identical or similar parts of the microfluidic devices differ in steps of 100 (the fluid channels or sample chambers have for example the reference numbers 106, 206, 306, and 406). The sensor chip 10 is now integrated into a hole in the (usual) bottom wall 205 with its substrate side oriented towards the fluid channel 206. The chip 10 may be fixed to the wall 205 by a ring of glue 203, and it is connected via flip-chip bumps 204 to a flex foil or MID 202. Additional mechanical stiffness may be added to the chip 10 and/or the flex foil 202 if necessary.

FIG. 10 shows a modification of the design of FIGS. 8 and 9. In the microfluidic device 300, the sensor chip 10 is integrated into the bottom wall 302 of a fluid channel 306 and sealed thereto with glue 303. Moreover, a signal processing chip 20 is attached to the lower sensitive side of the sensor chip 10 by flip-chip bumps 304. This method realizes a very high bandwidth and low noise in the detection system due to the very short interconnects between the sensor 10 and the signal processing chip 20. The Figure further shows as an optional design feature that the bottom wall of the microfluidic device 300 is constituted by a flex foil or MID 302 to which the signal processing chip 20 can be directly bonded.

FIG. 11 shows the application of the present invention to microtiter plate 400. A microtiter plate comprises sample chambers or wells 406 separated by vertical walls 401 (cf. WO 2005/038911 A1, which is incorporated into the present application by reference). The bottoms of the wells 406 in a standard microtiter plate are removed and replaced by a plurality of sensors 10 as in FIG. 8 or 9. As shown in the Figure, the sensor chips 10 may for example be bonded to a flex foil 402, sealed by glue 403, and supported by a layer 405. If desired, the substrate side of the sensor chips 10, which points to the liquid, may be covered with gold (Au) or another material to ease the surface chemistry. It is also possible to attach the sensor/flex combination to the wells without removing the bottoms.

The embodiments described above may be modified in such a way that the flex foils or MIDs comprise no galvanic connection between one of the chips and an external reader station. Instead, a wireless connection can power the sensor and the chip. Data and control data is then transferred over the same connection. For that purpose the sensor or the signal-processing chip or the flex foil/MID may comprise communications means like an inductive or RF antenna or a photovoltaic cell.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A microchip assembly, comprising:
a) a microelectronic chip with coupling circuits on a substrate, the coupling circuits being adapted to perform and process a wireless physical interaction over a short distance;
b) a sample location for providing an object that can interact with the coupling circuits;
wherein the substrate is disposed between the coupling circuits and the sample location.

2. The microchip assembly according to claim 1, wherein the thickness of the substrate is less than 100 μm.

3. The microchip assembly according to claim 1, wherein the coupling circuits comprise circuits for the generation of an electromagnetic field or circuits for the detection of an electromagnetic field.

4. The microchip assembly according to claim 1, wherein a side of the substrate facing the sample location is covered with a coating that improves the surface chemistry.

5. The microchip assembly according to claim 1, wherein the coupling circuits are covered on a side opposite to the substrate with a carrier layer which comprises VIAs for contacting the coupling circuits.

6. The microchip assembly according to claim 1, wherein a side of the chip opposite to the substrate is bonded to a signal processing chip.

7. The microchip assembly according to claim 1, further comprising means for a wireless data communication.

8. A microfluidic device comprising a microchip assembly according to claim 1, wherein the sample location is a sample chamber of the microfluidic device.

9. The microfluidic device according to claim 8, wherein the microelectronic chip is attached to an inner side of a wall of the sample chamber.

10. The microfluidic device according to claim 9, wherein a mechanical support is disposed between the chip and said wall.

11. The microfluidic device according to claim 8, wherein the chip is integrated into a wall of the sample chamber.

12. The microfluidic device of claim 8, wherein at least one wall of the sample chamber is a molded interconnection device or a flex foil.

13. The microfluidic device according to claim 8, wherein a side of the chip opposite to the substrate is scaled against the sample location.

14. A process for the production of the microelectronic chip for a microchip assembly according to claim 1, comprising the following steps:
a) generation of the coupling circuits on a substrate block of a first thickness;
b) reducing the first thickness of the substrate block, to the thickness of the final substrate.

15. The process according to claim 14, wherein the coupling circuits are attached to a carrier layer before the thickness reduction in step b).
